(19) United States
(12) Patent Application Publication
(10) Pub. No.: US 2006/0211157 A1
(43) Pub. Date: Sep. 21, 2006

(54) Novel CMP endpoint detection process

(75) Inventors: Stanley M. Smith, Allen, TX (US); Christopher L. Borst, Plano, TX (US)

Correspondence Address: TEXAS INSTRUMENTS INCORPORATED, P O BOX 655474, M/S 3999, DALLAS, TX, 75265, US

(73) Assignee: Texas Instruments Inc., Dallas, TX (US)

(21) Appl. No.: 11/082,406

(22) Filed: Mar. 17, 2005

(51) Int. Cl. H01L 21/4763

(52) U.S. Cl. 438/6; 438/692; 438/633

(57) ABSTRACT

The present invention provides a method for polishing a layer of material, a method for manufacturing a damascene interconnect structure, and a method for manufacturing an integrated circuit. The method for polishing a layer of material, among other steps, includes obtaining a substrate (310) having a layer of material (330) located thereover, and polishing the layer of material (330) using a polishing surface (410). The step of polishing the layer of material may include subjecting the layer of material (330) to a first polishing process using a first endpoint detection method, the first polishing process removing a portion of the layer of material, and subjecting remaining portions (420) of the layer of material (330) to a second polishing process using a second different optical endpoint detection method.

### TECHNICAL FIELD OF THE INVENTION

The present invention is directed, in general, to a CMP process and, more specifically, to a novel CMP endpoint detection process.

### BACKGROUND OF THE INVENTION

As integrated circuits become more and more dense, the width of interconnect layers that connect transistors and other devices of the integrated circuit to each other is reduced. As the width decreases, the resistance increases. Accordingly, many companies are looking to switch from a traditional aluminum interconnect to other type interconnects. Copper and tungsten interconnects, among others, are a few of the more advanced interconnects that are currently being used. Unfortunately, both copper and tungsten are very difficult to etch in a semiconductor process flow. Therefore, damascene processes have been proposed to form these interconnects.

A typical damascene process consists of forming an interlevel dielectric 12 over a semiconductor body 10, as shown in FIG. 1A. The interlevel dielectric 12 is then patterned and etched to remove the dielectric material from the areas 14 where the interconnect lines are desired, as shown in FIG. 1B. In a dual damascene process, via holes are also formed at this time. Referring to FIG. 1C, a barrier layer 16 is then deposited over the structure including over the dielectric 12 and in the areas 14 where the dielectric has been removed. A metal seed layer 18 is then formed over the barrier layer 16. A metal layer 20 is then formed from the metal seed layer 18 using, for example, an electroplating process, as shown in FIG. 1D. Chemical-mechanical polishing (CMP) is then used to planarize the excess metal layer 20 to be level with the top of the interlevel dielectric layer 12, resulting in the metal plug 21, as shown in FIG. 1E.

Today's CMP processes attempt to be gentle to the substrate surface, and for this reason, often use metal polish distributed across two or more tables, or “platens”, and thus polishing surfaces. In this typical scenario, the first platen uses a high down force (HDF) process to remove bulk portions of the metal layer 20, and the second platen uses a slow, gentle, lower down force (LDF) process to polish the remaining metal layer 20 until all areas of the substrate surface are clear of the metal layer 20, resulting in the metal plug 21. The problem typically encountered is how to balance the time between platens by removing a target amount of bulk metal layer 20 on the first platen, and then gently remove the remaining metal layer 20 on the second platen, all the while doing so in a controllable and repeatable manner. Prior art methods have generally been unable to balance the time between the platens in a controllable and repeatable manner, such that an optimal metal plug 21 may be manufactured.

Accordingly, what is needed in the art is a novel CMP endpoint detection process that does not experience the drawbacks of the prior art CMP processes.

### SUMMARY OF THE INVENTION

To address the above-discussed deficiencies of the prior art, the present invention provides a method for polishing a layer of material, a method for manufacturing a damascene interconnect structure, and a method for manufacturing an integrated circuit. The method for polishing a layer of material, among other steps, includes obtaining a substrate having a layer of material located thereover, and polishing the layer of material using a polishing surface. The step of polishing the layer of material may include subjecting the layer of material to a first polishing process using a first endpoint detection method, the first polishing process removing a portion of the layer of material, and subjecting remaining portions of the layer of material to a second polishing process using a second different optical endpoint detection method.

As previously indicated, the present invention further includes a method for manufacturing a damascene interconnect structure. The method for manufacturing the damascene interconnect structure includes, without limitation, forming a layer of conductive material within an opening and over an upper surface of a dielectric layer, and polishing the layer of conductive material to form an interconnect plug. The polishing of the layer of conductive material, again without limitation, may include subjecting the layer of conductive material to a first polishing process with a polishing surface and using a first endpoint detection method, the first polishing process removing a portion of the layer of conductive material, and subjecting remaining portions of the layer of conductive material to a second polishing process with the polishing surface and using a second different optical endpoint detection method.

The foregoing has outlined preferred and alternative features of the present invention so that those skilled in the art may better understand the detailed description of the invention that follows. Additional features of the invention will be described hereinafter that form the subject of the claims of the invention. Those skilled in the art should appreciate that they can readily use the disclosed conception and specific embodiment as a basis for designing or modifying other structures for carrying out the same purposes of the present invention. Those skilled in the art should also realize that such equivalent constructions do not depart from the spirit and scope of the invention.

### BRIEF DESCRIPTION OF THE DRAWINGS

The invention is best understood from the following detailed description when read with the accompanying FIGUREs. It is emphasized that in accordance with the standard practice in the semiconductor industry, various features are not drawn to scale. In fact, the dimensions of the various features may be arbitrarily increased or reduced for clarity of discussion. Reference is now made to the following descriptions taken in conjunction with the accompanying drawings, in which:

Prior Art FIGS. 1A-1E illustrate a conventional damascene process flow;

FIG. 2 illustrates a flow diagram of a method for polishing a layer of material in accordance with the principles of the present invention;

FIG. 3 illustrates a cross-sectional view of a partially completed interconnect structure manufactured in accordance with the principles of the present invention;

FIG. 4 illustrates a cross-sectional view of the partially completed interconnect structure illustrated in FIG. 3 after subjecting the layer of material to a first polishing process using a first polishing surface;

FIG. 5 illustrates a cross-sectional view of the partially completed interconnect structure illustrated in FIG. 4 after subjecting the polished layer of material to a second polishing process using the first polishing surface;

FIG. 6A illustrates an example data output produced using the multi-stage endpoint technique embodied in the present invention;

FIGS. 6B-6C illustrate reflectance information at point B and point C in the graph of FIG. 6A;

FIG. 7 illustrates a cross-sectional view of the partially completed interconnect structure illustrated in FIG. 5 after subjecting the film of material to a third polishing process using a second different polishing surface, as well as other processes;

FIG. 8 illustrates improved CMP statistical process thickness control that may be achieved using the principles of the present invention;

FIG. 9 illustrates an exemplary cross-sectional view of an integrated circuit (IC) incorporating interconnect structures constructed according to the principles of the present invention.

### DETAILED DESCRIPTION

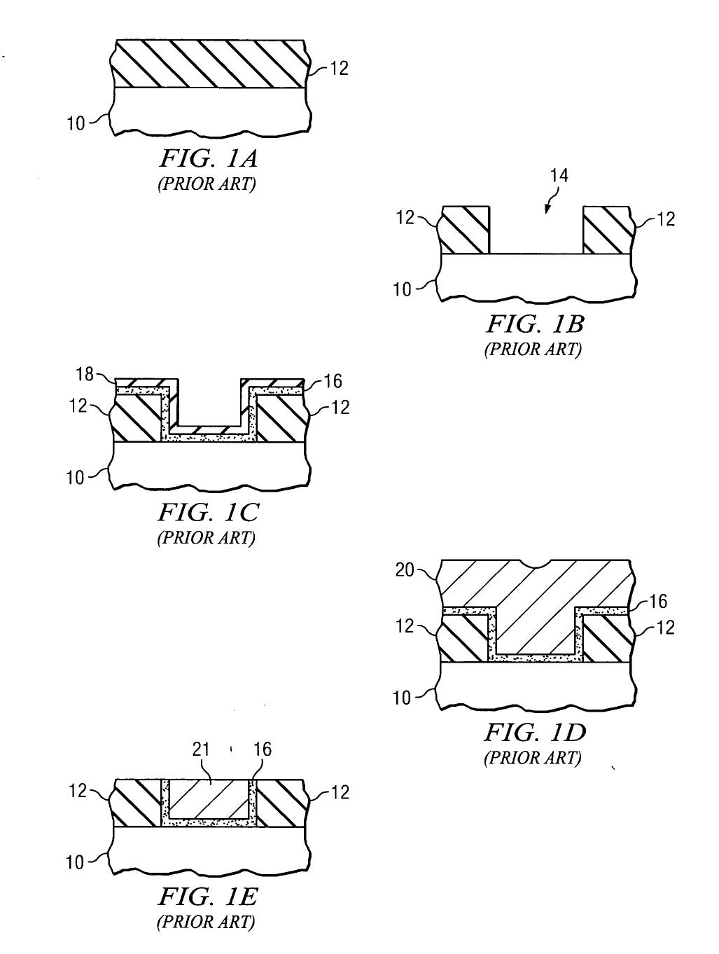

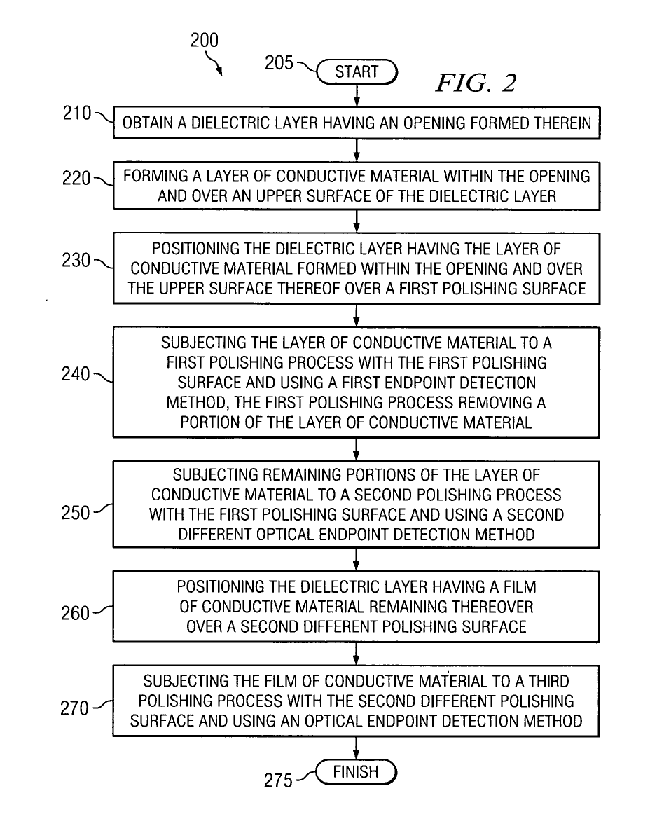

Referring initially to FIG. 2, illustrated is a flow diagram 200 of a method for polishing a layer of material. The method for polishing the layer of material in accordance with the principles of the present invention, as will be illustrated, may be incorporated into a process flow for manufacturing damascene interconnect structures, as well as a process flow for manufacturing integrated circuits including the damascene interconnect structures, among others, without departing from the scope of the present invention. As the method for polishing the layer of material, in one embodiment, forms a portion of the method for manufacturing damascene interconnect structures in accordance with the principles of the present invention, the flow diagram will be discussed with respect to the method for manufacturing damascene interconnect structures. Nevertheless, the discussion of the two ideas in tandem should in no way be used to limit the scope of each of the individual ideas.

Turning back to FIG. 2, the method for polishing the layer of material, in this instance a layer of conductive material, begins in a start step 205. Thereafter, in a step 210, a substrate, such as a dielectric layer, having an opening formed therein may be obtained. A layer of conductive material may be formed within the opening in the dielectric layer in a subsequent step 220. After forming the layer of conductive material, the dielectric layer having the layer of conductive material formed within the opening and over the upper surface thereof may be placed over a first polishing surface in a step 230.

The layer of conductive material, in a step 240, may be subjected to a first polishing process with the first polishing surface. In accordance with the principles of the present invention, the first polishing process uses an endpoint detection method to remove a portion of the layer of conductive material. In many embodiments the first polishing process removes a substantial portion of the layer of conductive material. The endpoint detection method used in step 240, in an exemplary embodiment, is an eddy current endpoint detection method. The eddy current endpoint detection method is particularly useful when used in conjunction with a high down force (HDF) process advantageously used in step 240. Those skilled in the art appreciate that other detection methods are within the scope of the present invention.

Thereafter, in a step 250, remaining portions of the layer of conductive material may be subjected to a second polishing process with the first polishing surface. In accordance with the principles of the present invention, the second polishing process uses a second different optical endpoint detection method to remove all or a part of the remaining portions of the layer of conductive material. In an exemplary embodiment, the optical endpoint detection method allows the second polishing process to stop prior to completely removing the entire layer of conductive material, thereby leaving a film of conductive material remaining over the dielectric layer. While less likely, another embodiment might exist wherein the second polishing process accurately and completely removes all of the remaining portions of the layer of conductive material. This embodiment would most likely be used in conjunction with a two platen CMP tool.

In the embodiment wherein the film of conductive material remains over the dielectric layer after the second polishing process, the dielectric layer having the film of conductive material thereover may be moved to be located over a second different polishing surface. This might occur in the optional step 260. Thereafter, in an optional step 270, the film of conductive material may then be subjected to a third polishing process using the second different polishing surface. In accordance with one embodiment, the third polishing process could use an optical endpoint detection method to determine when to terminate the third polishing process. In another embodiment, the optical endpoint detection method could be a similar process to that used in step 250. Nevertheless, other optical endpoint detection methods could be used. After completing step 270, the process could then stop in a finish step 275, or repeat itself by returning to step 205 with a new dielectric layer having an opening therein.

Nevertheless, it goes without saying that certain steps neither discussed nor shown could be conducted prior to the finish step 275. One example is the conventional removal (e.g., polishing) of any remaining barrier/adhesion layer located over an upper surface of the dielectric layer. This step might be conducted after step 270, however, prior to the finish step 275. A number of other steps might also exist.

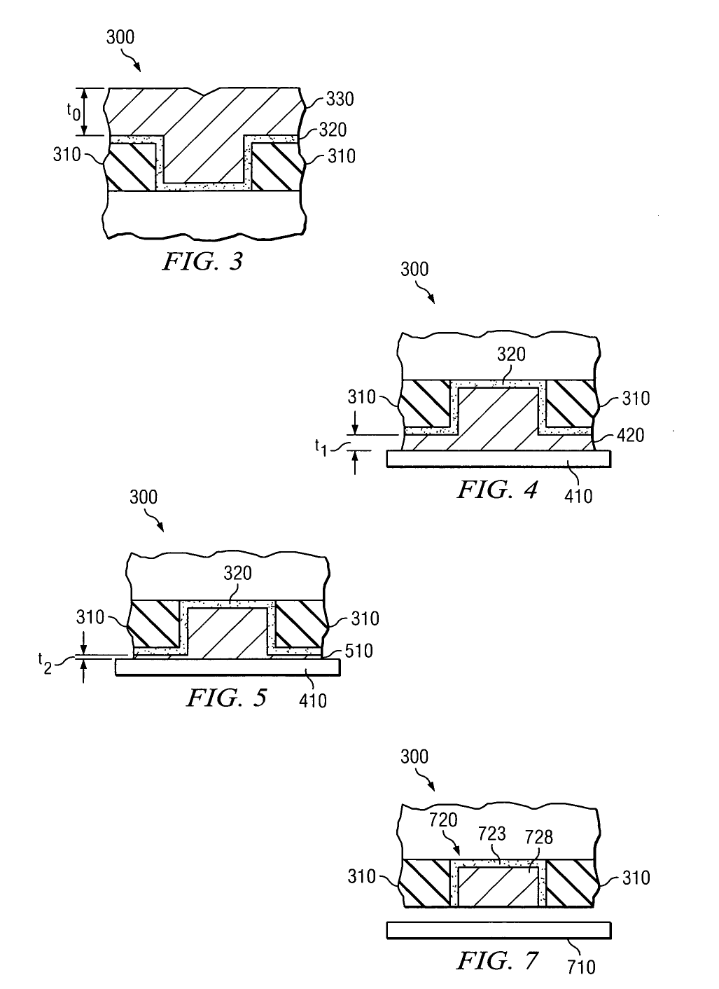

Turning now to FIGS. 3-8, illustrated are cross-sectional views of detailed manufacturing steps illustrating how one might manufacture an interconnect structure in accordance with the principles of the present invention, as well as graphs and tables in support thereof. FIG. 3 illustrates a cross-sectional view of a partially completed interconnect structure 300 manufactured in accordance with the principles of the present invention. The interconnect structure 300 illustrated in FIG. 3 includes a substrate 310 having an opening formed therein. The number of different materials that the substrate 310 may comprise is almost unlimited. Nevertheless, one advantageous embodiment exists wherein the substrate 310 comprises a dielectric layer.

Conventionally formed over the substrate 310 and within the opening therein may be a barrier/adhesion layer 320. The barrier/adhesion layer 320 is typically desired to help the layer of material 330 easily adhere to the substrate 310. The barrier/adhesion layer 320 is also typically desired wherein the layer of material 330 comprises a material that might be detrimental to devices that might be located proximate thereto. For example, in instances wherein the layer of material 330 comprises copper, the barrier/adhesion layer 320 might comprise tantalum/tantalum nitride. In the instance wherein the layer of material 330 comprises tungsten, the barrier/adhesion layer 320 might comprise titanium/titanium nitride/tungsten nitride.

As shown in FIG. 3, a layer of material 330 is conventionally formed over a top surface and within the opening in the substrate 310. The layer of material 330, which in the embodiment shown in FIG. 3 comprises a layer of conductive material, may comprise a magnitude of different materials while staying within the purview of the present invention. For instance, many embodiments exist wherein the layer of material 330 comprises copper or tungsten. Other embodiments also exist wherein the layer of material 330 comprises another similar material.

Similar to the material composition of the layer of material 330, the thickness (t₀) of the layer of material 330 may vary greatly. It is important, however, that the layer of material 330 substantially fill the opening in the substrate 310. Depending on the size of the opening in the substrate 310, as well as the thickness of the substrate 310 itself, the initial thickness (t₀) of the layer of material 330 should range from about 200 nm to about 2000 nm, and more particularly about 500 nm to about 1000 nm. The present invention should, nonetheless, not be limited to such thicknesses.

The method for forming the layer of material 330 may take on a number of different processes and techniques and remain within the scope of the present invention. For instance, in one embodiment of the invention the layer of material 330 is formed by electroplating the layer of material 330 within the opening and over the upper surface of the substrate 310 using a conventional seed layer formed over the barrier/adhesion layer 320. In an alternative embodiment, however, the layer of material 330 is deposited within the opening and over the upper surface of the substrate 310 using a conventional physical vapor deposition (PVD) or chemical vapor deposition (CVD) process. Other known or hereafter discovered process could also be used.

Turning now to FIG. 4, illustrated is a cross-sectional view of the partially completed interconnect structure 300 illustrated in FIG. 3 after subjecting the layer of material 330 to a first polishing process with a first polishing surface 410, similar to that mentioned in step 240 of FIG. 2. The first polishing process, in an exemplary embodiment, is typically designed to remove a substantial portion of the layer of material 330. For example, in one advantageous embodiment the first polishing process is configured to remove from about 50 percent to about 80 percent of the layer of material 330. To quickly remove these larger amounts of the layer of material 330, the first polishing process is often a high down force (HDF) process. For example, depending on a number of different criteria, the HDF process used in the first polishing process typically uses a down force ranging from about 2 psi to about 5 psi. However, those skilled in the art understand that this down force may vary, and thus the given values should not be used to limit the scope of the present invention.

Unique to the present invention, a first endpoint detection method is associated with the first polishing process to determine when and if the first polishing process should terminate. While a number of different endpoint detection methods exist and could be used, an exemplary embodiment of the present invention uses an eddy current detection method. As those skilled in the art appreciate, the eddy current method works by generating and measuring an eddy current created within the layer of material 330 to determine the thickness of the layer of material 330 being polished. In this embodiment, the first polishing process would continue until a desired amount of change in the eddy current measurement is detected. It is believed that the desired amount of change in the eddy current measurement indicates that the polished layer of material 420 is about 300 nm thick. While the eddy current method has been discussed in somewhat detail, other endpoint detection means could nevertheless be used for the first endpoint detection method, and remain within the purview of the present invention.

What results after polishing the layer of material 330 using the first polishing process is a polished layer of material 420. The polished layer of material 420, as indicated in FIG. 4, might have a resulting average thickness (t₁) after being subjected to the first polishing process. In an exemplary embodiment, this average thickness (t₁) would range from about 20 percent to about 50 percent of the average thickness of the original layer of material 330. Accordingly, in the embodiment previously discussed, the average thickness (t₁) of the polished layer of conductive material 420 might range from about 150 nm to about 400 nm. In an exemplary embodiment, the thickness (t₁) would range from about 200 nm to about 400 nm, and particularly about 300 nm.

Turning now to FIG. 5, illustrated is a cross-sectional view of the partially completed interconnect structure 300 illustrated in FIG. 4 after subjecting the polished layer of material 420 to a second polishing process, similar to that mentioned in step 250 of FIG. 2. It should be noted that the second polishing process is again conducted with the first polishing surface 410. As will be established below, certain advantages are achieved by conducting both the first and second polishing processes with the same polishing surface 410.

While not being limited to such, the second polishing process, in an exemplary embodiment, is designed to remove all but a film of material 510. To accurately and reproducibly leave only this film of material 510, the second polishing process often uses a low down force (LDF) process. For example, depending on a number of different criteria, the LDF process typically uses a down force ranging from about 0.5 psi to about 2 psi. Again, those skilled in the art understand that this down force may vary, and thus the values given should not be used to limit the scope of the present invention.

Unique to the present invention, a second different optical endpoint detection method is used with the second polishing process to determine when and if the second polishing process should terminate. While a number of different optical endpoint detection methods may exist, an exemplary embodiment of the present invention uses a reflectance based endpoint detection method, such as that found on the ISRM tool that may be obtained from Applied Materials, Inc. Nonetheless, any known or hereafter discovered optical endpoint detection method or tool might be used, as long as it remains within the principles of the present invention.

The film of the material 510, as indicated in FIG. 5, might have a resulting average thickness (t₂) after being subjected to the second polishing process. In an exemplary embodiment, this average thickness (t₂) would range from about 40 nm to about 90 nm. In one advantageous embodiment, the thickness (t₂) would range from about 50 nm to about 80 nm.

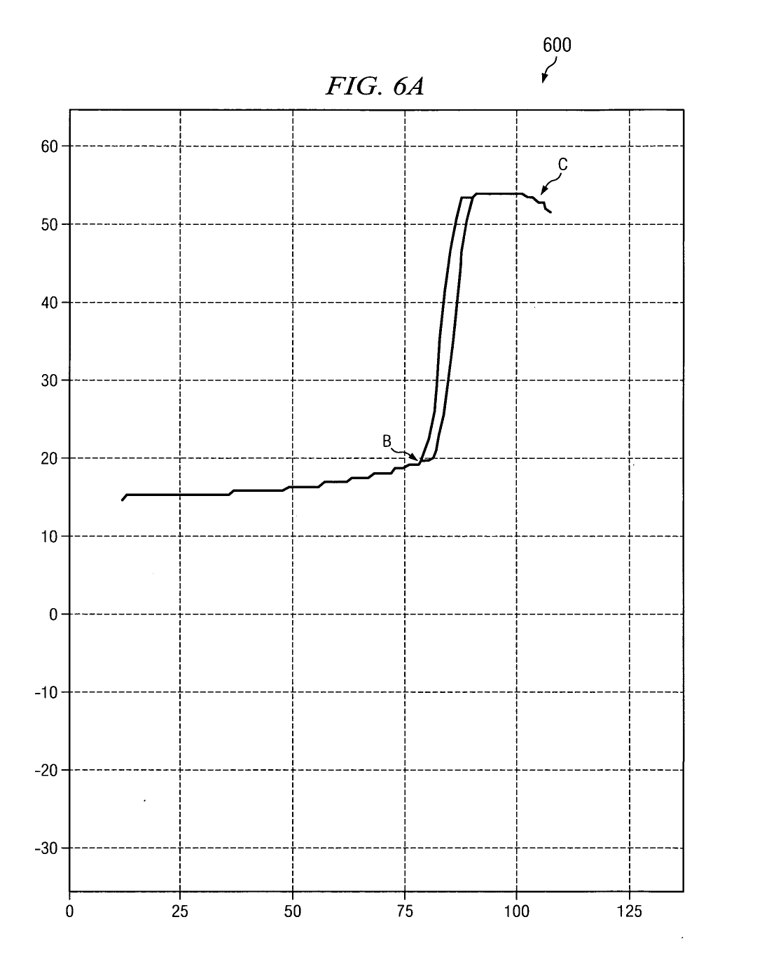

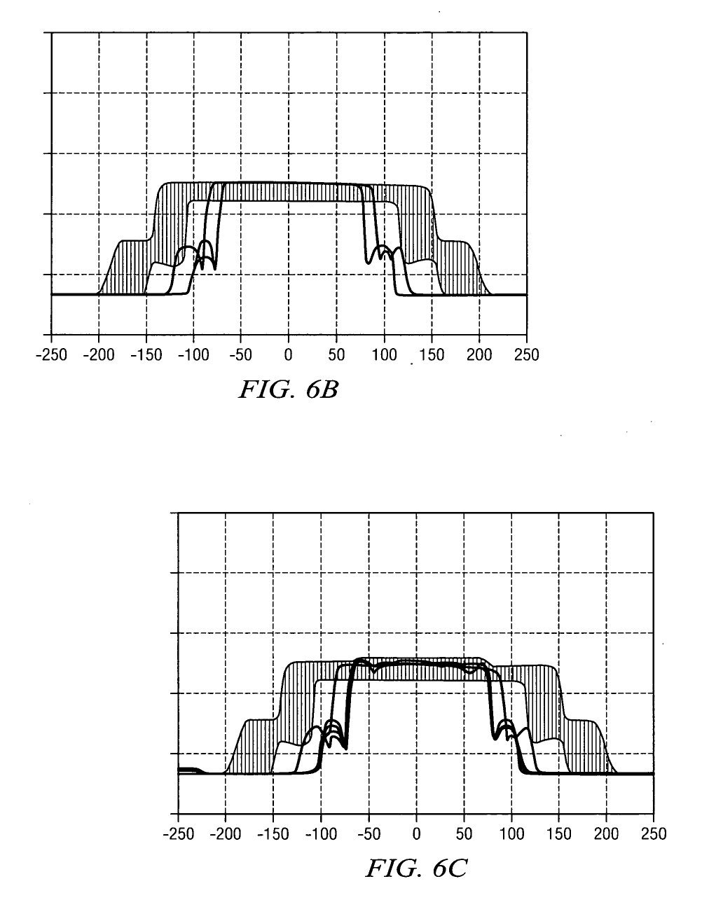

Turning briefly to FIG. 6A, illustrated is an example data output produced using the multi-stage endpoint technique embodied in the present invention. The graph 600 of FIG. 6A illustrates an endpoint signal generated on a single platen with a single polishing surface using the inventive aspects of the present invention. The trace obtained from about 12 seconds to about 78 seconds (point B) consists of example data output from an eddy current sensor. The first polishing process terminates, in this example, at 78 seconds, due to the desired amount of change in the eddy current signal. This change in the eddy current signal correlates to the desired bulk film thickness remaining. The trace obtained from about 78 seconds (point B) to about 107 seconds (point C) consists of an example data output from an optical endpoint detection sensor. Thus, the second polishing process begins, in this example, at about 78 seconds (point B) and terminates at about 107 seconds (point C), due to the desired change in the reflectance value. This change in the reflectance value correlates to the desired thin-film thickness at which point the conductive film begins to lose reflectance. Process control using this multi-step endpoint process results in the maximum desired amount of conductive film removal during both the first and second polishing processes, with complete real-time endpoint visibility. The method of determining the endpoint at point C in accordance with the principles of the present invention results in an exceedingly consistent amount of conductive material entering the subsequent processing steps.

Turning now to FIGS. 6B and 6C, illustrated is reflectance information at point B and point C in the graph 600 of FIG. 6A. As indicated above, at point B the first HDF polishing process has ended and the first endpoint detection method has been turned off. Thus, at point B the second LDF polishing process begins and the second different optical endpoint detection method also begins. Accordingly, FIG. 6B illustrates reflectance information at point B and FIG. 6C illustrates reflectance information at point C. As pointed out by FIG. 6B, at point B in graph 600 the layer of material is fully reflective and uniform across the wafer diameter (e.g., fully reflective). However, as pointed out by FIG. 6C, at point C in the graph 600 the reflectance is no longer fully reflective, and begins to materially drop off. In an exemplary situation, this is the point at which the second polishing process with the first polishing surface would terminate. It is believed that in most instances the reflectance changes from completely reflective to not completely reflective when the film of material 510 has an average thickness (t₂) ranging from about 50 nm to about 80 nm, as indicated above.

Turning now to FIG. 7, illustrated is a cross-sectional view of the partially completed interconnect structure 300 illustrated in FIG. 5 after subjecting the film of material 510 to a third polishing process, similar to that mentioned in step 270 of FIG. 2. In an exemplary embodiment of the invention, the third polishing process is conducted with a second different polishing surface 710 than the first and second polishing processes. However, in certain embodiments, particularly those using a two-platen polishing tool, the third polishing process is conducted using the same polishing surface 410 as the first and second polishing processes. The third polishing process, in one advantageous embodiment, is designed to remove any remaining portions of the film of material 510. To accomplish this without creating high topography in the final interconnect plug 728, the third polishing process is typically a low down force (LDF) process. For example, depending on a number of different criteria, the LDF process used for the third polishing process typically uses a down force ranging from about 0.5 psi to about 2.0 psi. The present invention should not be limited to such down forces.

Unique to the present invention, a third endpoint detection method is associated with the third polishing process to determine when and if the third polishing process should terminate. While a number of different endpoint detection methods exist and could be used, an exemplary embodiment of the present invention uses an optical endpoint detection method. In one advantageous embodiment, the optical endpoint method used in the third polishing process is substantially similar to that used in the second polishing process.

In certain embodiment a portion of the barrier/adhesion layer 320 will remain over an upper surface of the substrate 310. In these instances, another polishing process (not shown) may be required to remove any remaining barrier/adhesion layer 320. Those skilled in the art understand the conventional processes that might be used to remove any remaining barrier/adhesion layer 320. What results after polishing the film of material 510 using the third polishing process and removing any remaining portions of the barrier/adhesion layer 320 is a completed interconnect 720. The interconnect 720 of the embodiment of FIG. 7 includes an adhesion/barrier layer 723 and an interconnect plug 728.

The present invention provides a number of advantages over that which might be provided by conventional methods. For example, the present invention provides continuous endpoint monitoring during the entire polishing process, which does not leave any “blind” times during which the material layer (e.g., conductive layer) is polished according to time only. Additionally, the present invention provides a method for ensuring a continuous, thin film of material covering the substrate as it transitions from the first polishing surface to the second polishing surface (e.g., from the second polishing process to the third polishing process). This, in turn, provides a reasonable degree of comfort when conducting the final polish that it may be precisely accomplished without either over or under polishing.

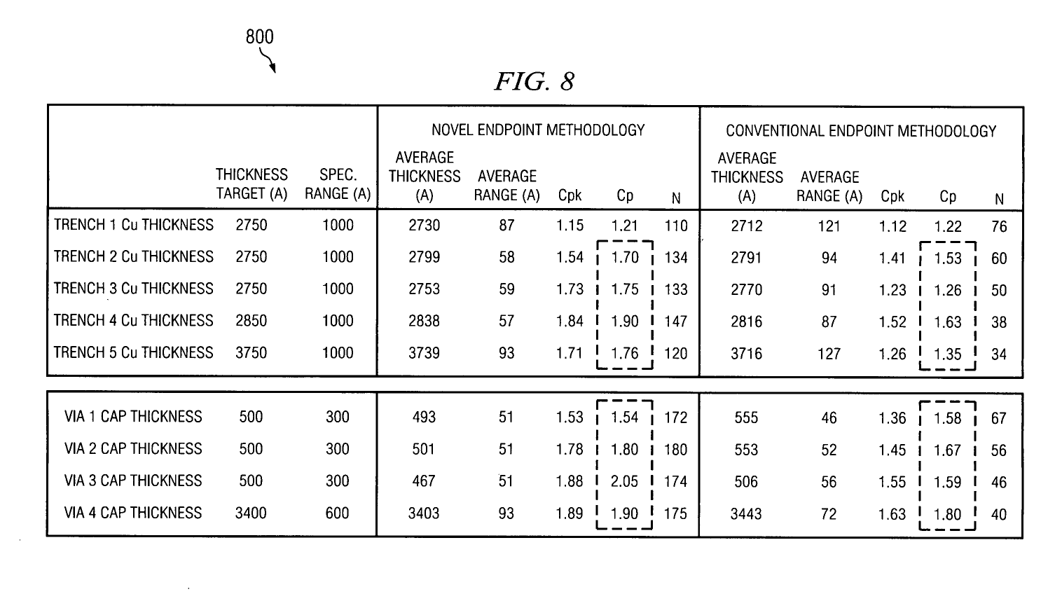

As illustrated in the table 800 of FIG. 8, the increased control leads to improved CMP statistical process thickness control. Specifically, as illustrated in FIG. 8, the Cp, which is basically a measurement of the wafer-to-wafer consistency of the interconnect plug 728 thicknesses relative to a specification, is higher. Accordingly, the thickness distribution is tighter. Additionally, the present invention provides a means for polishing as much of the layer of material with the first polishing surface as possible, enabling shorter times for polishing with the second polishing surface. Obviously, this provides increased throughput.

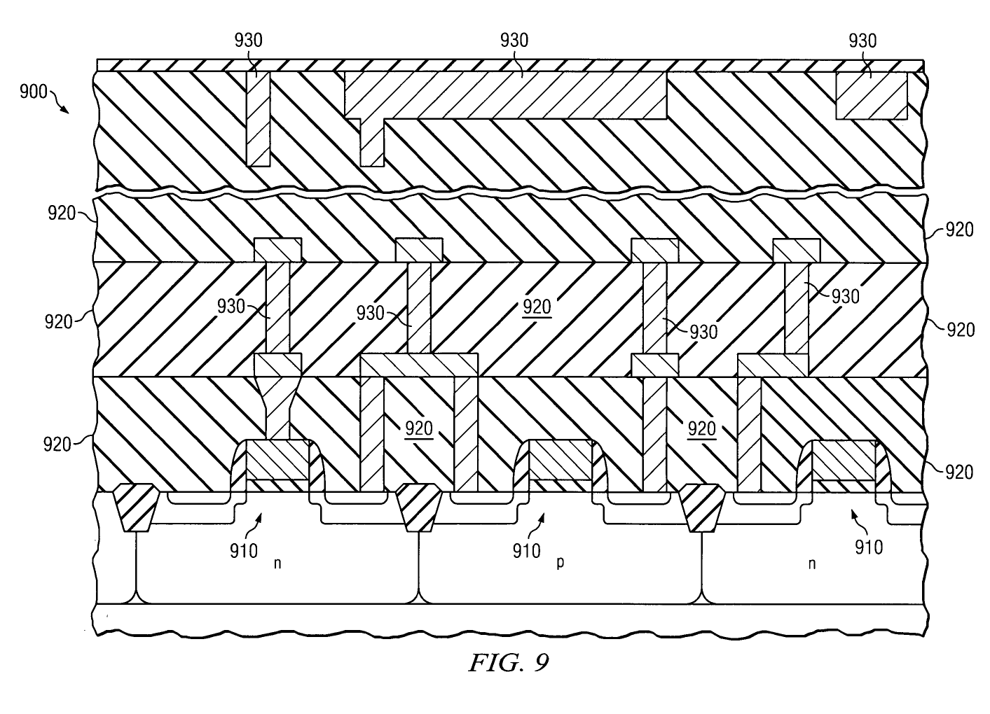

Referring now to FIG. 9, illustrated is an exemplary cross-sectional view of an integrated circuit (IC) 900 incorporating interconnect structures 930 constructed according to the principles of the present invention. The IC 900 may include devices, such as transistors used to form CMOS devices, BiCMOS devices, Bipolar devices, as well as capacitors or other types of devices. The IC 900 may further include passive devices, such as inductors or resistors, or it may also include optical devices or optoelectronic devices. Those skilled in the art are familiar with these various types of devices and their manufacture. In the particular embodiment illustrated in FIG. 9, the IC 900 includes transistor devices 910 having dielectric layers 920 located thereover. Additionally, interconnect structures 930 are located within the dielectric layers 920 to interconnect various devices, thus, forming the operational integrated circuit 900.

Although the present invention has been described in detail, those skilled in the art should understand that they could make various changes, substitutions and alterations herein without departing from the spirit and scope of the invention in its broadest form.

What is claimed is:

1. A method for polishing a layer of material, comprising:
obtaining a substrate having a layer of material located thereover; and
polishing the layer of material using a polishing surface, including;
subjecting the layer of material to a first polishing process using a first endpoint detection method, the first polishing process removing a portion of the layer of material; and
subjecting remaining portions of the layer of material to a second polishing process using a second different optical endpoint detection method.

2. The method as recited in claim 1 wherein the second polishing process leaves a film of material remaining over the substrate, and further including polishing the film of material using a second different polishing surface.

3. The method as recited in claim 2 wherein the film of material has an average thickness ranging from about 40 nm to about 90 nm.

4. The method as recited in claim 2 wherein polishing the film of material using a second different polishing surface includes using an optical endpoint detection method.

5. The method as recited in claim 1 wherein the first endpoint detection method includes an eddy current endpoint detection method.

6. The method as recited in claim 1 wherein the second different optical endpoint detection method includes a reflectance based endpoint detection method.

7. The method as recited in claim 6 wherein the second polishing process continues until a reflectance value obtained from the reflectance based endpoint detection method begins to materially drop off.

8. The method as recited in claim 1 wherein the layer of material is copper or tungsten.

9. The method as recited in claim 1 wherein removing a portion of the layer of material includes removing from about 50 percent to about 80 percent of a thickness of the layer of material.

10. The method as recited in claim 9 wherein removing from about 50 percent to about 80 percent of the thickness of the layer of material includes leaving from about 200 nm to about 400 nm of the thickness.

11. A method for manufacturing a damascene interconnect structure, comprising:
forming a layer of conductive material within an opening and over an upper surface of a dielectric layer; and
polishing the layer of conductive material to form an interconnect plug using a polishing surface, including;
subjecting the layer of conductive material to a first polishing using a first endpoint detection method, the first polishing process removing a portion of the layer of conductive material; and
subjecting remaining portions of the layer of conductive material to a second polishing process using a second different optical endpoint detection method.

12. The method as recited in claim 11 wherein the second polishing process leaves a film of conductive material remaining over the dielectric layer, and further including polishing the film of material using a second different polishing surface.

13. The method as recited in claim 12 wherein the film of conductive material has an average thickness ranging from about 40 nm to about 90 nm.

14. The method as recited in claim 12 wherein polishing the film of material using a second different polishing surface includes using an optical endpoint detection method.

15. The method as recited in claim 11 wherein the first endpoint detection method includes an eddy current endpoint detection method.

16. The method as recited in claim 11 wherein the second different optical endpoint detection method includes a reflectance based endpoint detection method.

17. The method as recited in claim 16 wherein the second polishing process continues until a reflectance value obtained from the reflectance based endpoint detection method begins to materially drop off.

18. The method as recited in claim 11 wherein the layer of conductive material includes copper or tungsten.

19. The method as recited in claim 11 wherein removing a portion of the layer of conductive material includes removing from about 50 percent to about 80 percent of a thickness of the layer of conductive material.

20. The method as recited in claim 19 wherein removing from about 50 percent to about 80 percent of the thickness of the layer of conductive material includes leaving from about 200 nm to about 400 nm of the thickness.

21. A method for manufacturing an integrated circuit, including;
forming transistor devices over a substrate;
placing a dielectric layer over the transistor devices; and
creating damascene interconnect structures within the dielectric layer for contacting the transistor devices and forming an operational integrated circuit, including;
forming a layer of conductive material within an opening and over an upper surface of the dielectric layer;
subjecting the layer of conductive material to a first polishing process with a polishing surface and using a first endpoint detection method, the first polishing process removing a portion of the layer of conductive material; and
subjecting remaining portions of the layer of conductive material to a second polishing process with the polishing surface and using a second different optical endpoint detection method.

22. The method as recited in claim 21 wherein the second polishing process leaves a film of conductive material remaining over the substrate, and further including polishing the film of material using a second different polishing surface.

23. The method as recited in claim 22 wherein polishing the film of material using a second different polishing surface includes using an optical endpoint detection method.
